(19) United States
(12) Patent Application Publication
(10) Pub. No.: US 2026/0253627 A1
(43) Pub. Date: Aug. 27, 2026

(54) MEMORY DEVICE

(71) Applicant: Kioxia Corporation, Tokyo (JP)

(72) Inventor: Kuniaki SUGIURA, Seoul (KR)

(73) Assignee: Kioxia Corporation, Tokyo (JP)

(21) Appl. No.: 19/240,578

(22) Filed: Jun. 17, 2025

(30) Foreign Application Priority Data
Feb. 25, 2025 (JP) 2025-028393

(51) Int. Cl. G11C 11/16

(52) U.S. Cl. CPC G11C 11/1675

(57) ABSTRACT

A first interconnect is coupled to a memory cell. A first driver generates a first potential based on a terminal voltage of the memory cell on the first interconnect. A comparison circuit outputs first data having a first level in a case where the first potential exceeds a reference potential and having a second level in a case where the first potential is lower than the reference potential. A register holds the first data and output a first signal having a level based on the first data. A second driver receives the first signal and responds to an instruction to apply stress to the memory cell to execute the application of the stress in a case where the first signal has the first level and not to execute the application of the stress in a case where the first signal has the second level.

### CROSS-REFERENCE TO RELATED APPLICATION

This application is based upon and claims the benefit of priority from Japanese Patent Application No. 2025-28393, filed Feb. 25, 2025, the entire contents of which are incorporated herein by reference.

### FIELD

Embodiments described herein relate generally to a memory device.

### BACKGROUND

Memory devices that use magnetism to store data have been known. Variations in characteristics of memory cells of the memory device are required to be small.

### BRIEF DESCRIPTION OF THE DRAWINGS

FIG. 1 illustrates functional blocks of a memory device of a first embodiment.

FIG. 2 is a circuit diagram of a memory cell array of the memory device of the first embodiment.

FIG. 3 is a perspective view of a part of the memory cell array of the memory device of the first embodiment.

FIG. 4 illustrates an exemplary cross section of a structure of a memory cell of the memory device of the first embodiment.

FIG. 5 illustrates an example of a change in the terminal voltage of the memory cell of the memory device of the first embodiment.

FIG. 6 illustrates some components of the memory device of the first embodiment and the coupling of the components.

FIG. 7 illustrates a flow of the operation of the memory device of the first embodiment.

FIG. 8 illustrates some components of a memory device of a second embodiment and the coupling of the components.

FIG. 9 illustrates a flow of the operation of the memory device of the second embodiment.

### DETAILED DESCRIPTION

In general, according to one embodiment, a memory device includes a memory cell, a first interconnect, a first driver, a comparison circuit, a register, and a second driver. The memory cell includes a variable resistance element and a switching element. The first interconnect is coupled to the memory cell. The first driver is configured to generate a first potential based on a terminal voltage of the memory cell on the first interconnect. The comparison circuit is configured to output first data having a first level in a case where the first potential exceeds a reference potential and output the first data having a second level in a case where the first potential falls to be lower than the reference potential. The register is configured to hold the first data and output a first signal having a level based on the first data. The second driver is configured to receive the first signal and respond to an instruction to apply stress to the memory cell from outside to execute the application of the stress in a case where the first signal has the first level and not to execute the application of the stress in a case where the first signal has the second level.

Embodiments will now be described with reference to the figures. In order to distinguish components having substantially the same function and configuration in an embodiment or over different embodiments from each other, an additional numeral or letter may be added to the end of each reference numeral or letter. In the following description, in an embodiment following an embodiment that is already described, different points from the already described embodiment are mainly described. The entire description of a particular embodiment applies to another embodiment unless an explicit mention is made otherwise, or an obvious elimination is involved.

Each functional block may be implemented as hardware, computer software, or their combination. It is not necessary that functional blocks be distinguished as in the following examples. Some of the functions may be implemented by functional blocks different from those illustrated below. Furthermore, an illustrated functional block may be divided into functional sub-blocks.

Steps in the flow of a method according to an embodiment are not limited to any of the illustrated orders, and may occur in an order different from the illustrated orders and/or may occur concurrently with another step or steps.

The specification and the claims, when mentioning that a particular (first) component is “coupled” to another (second) component, intend to cover both the form of the first component directly coupled to the second component and the form of the first component coupled to the second component via one or more components which are always or selectively conductive.

Embodiments will be described using a three-dimensional orthogonal coordinate system. A direction of an x axis is referred to as an X direction. A direction opposite to the X direction is referred to as a-X direction. A direction of a y axis is referred to as a Y direction. A direction opposite to the Y direction is referred to as a-Y direction. A direction of a z axis is referred to as a Z direction, and up indicates the Z direction. A direction opposite to the Z direction is referred to as a-Z direction.

### 1. First Embodiment

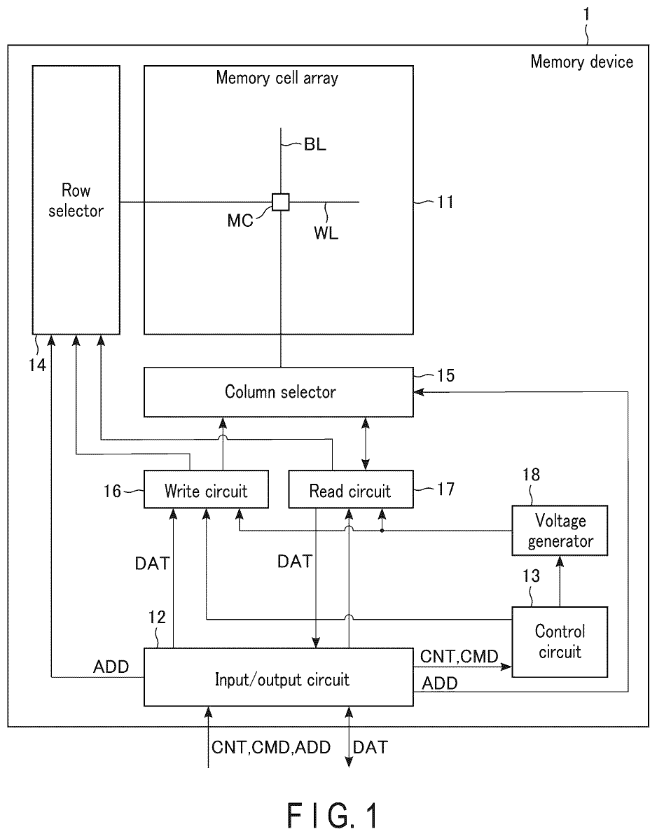

FIG. 1 illustrates functional blocks of a memory device of a first embodiment. A memory device 1 is a memory device that stores data using a material exhibiting variable resistance. As illustrated in FIG. 1, the memory device 1 includes a memory cell array 11, an input/output circuit 12, a control circuit 13, a row selector 14, a column selection circuit 15, a write circuit 16, a read circuit 17, and a voltage generation circuit 18.

The memory cell array 11 is a set of arranged memory cells MC. The memory cells MC can store data in a non-volatile manner. In the memory cell array 11, word lines WL and bit lines BL are located. Each memory cell MC is coupled to a single word line WL and a single bit line BL. Each word line WL is associated with a row. Each bit line BL is associated with a column. Selection of a single row and selection of a single column specify a single memory cell MC.

The input/output circuit 12 is a circuit that inputs and outputs data and signals. The input/output circuit 12 receives a control signal CNT, a command CMD, address information ADD, and data DAT from the outside of the memory device 1, or, in one example, from a memory controller. The input/output circuit 12 outputs the data DAT. The data DAT is data to be written in the case of data write in the memory device 1. The data DAT is read data in the case of data read from the memory device 1.

The voltage generation circuit 18 is a circuit that generates voltages of various magnitudes from voltages received from the outside of the memory device 1. The received voltages include a power supply voltage VDD and a ground voltage VSS. The voltage generation circuit 18 outputs voltages of constant magnitude used for data read. The voltage generation circuit 18 outputs a voltage of constant magnitude used for data write.

The write circuit 16 is a circuit that controls writing of data in the memory cell MC. The write circuit 16 receives the write data DAT from the input/output circuit 12 and receives the voltages for data write from the voltage generation circuit 18. The write circuit 16 outputs, based on control of the control circuit 13 and the write data DAT, a voltage and a current used for data write.

The read circuit 17 is a circuit that controls reading of data from the memory cell MC. The read circuit 17 receives the voltages for data read from the voltage generation circuit 18. The read circuit 17 determines what data is stored in the memory cell MC using the voltages used for data read based on the control of the control circuit 13. The determined data is supplied to the input/output circuit 12 as the read data DAT. The read circuit 17 includes a sense amplifier.

The row selector 14 is a circuit that selects a row of the memory cell MC. The row selector 14 receives the address information ADD from the input/output circuit 12. The row selector 14 receives the voltages for data write from the write circuit 16. The row selector 14 receives the voltages for data read from the read circuit 17. During data write, the row selector 14 uses the voltages for data write to bring one or more word lines WL associated with a row specified by the received address information ADD to a selected state. During data read, the row selector 14 uses the voltages for data read to bring the one or more word lines WL associated with the row specified by the received address information ADD to a selected state.

The column selection circuit 15 is a circuit that selects a column of the memory cell MC. The column selection circuit 15 receives the address information ADD from the input/output circuit 12. The column selection circuit 15 receives the voltages for data write from the write circuit 16. The column selection circuit 15 receives the voltages for data read from the read circuit 17. During data write, the column selection circuit 15 uses the voltages for data write to bring one or more bit lines BL associated with a column specified by the received address information ADD to a selected state. During data read, the column selection circuit 15 uses the voltages for data read to bring the one or more bit lines BL associated with the column specified by the received address information ADD to a selected state.

The control circuit 13 is a circuit that controls the operation of the memory device 1. The control circuit 13 receives the control signal CNT and the command CMD from the input/output circuit 12. The control circuit 13 controls the write circuit 16 and the read circuit 17 based on control instructed by the control signal CNT and the command CMD. Specifically, the control circuit 13 controls the write circuit 16 to supply the voltages received by the write circuit 16 from the voltage generation circuit 18 to the row selector 14 and the column selection circuit 15 during writing of data in the memory cell MC. The control circuit 13 controls the read circuit 17 to supply the voltages received by the read circuit 17 from the voltage generation circuit 18 to the row selector 14 and the column selection circuit 15 during reading of data from the memory cell MC.

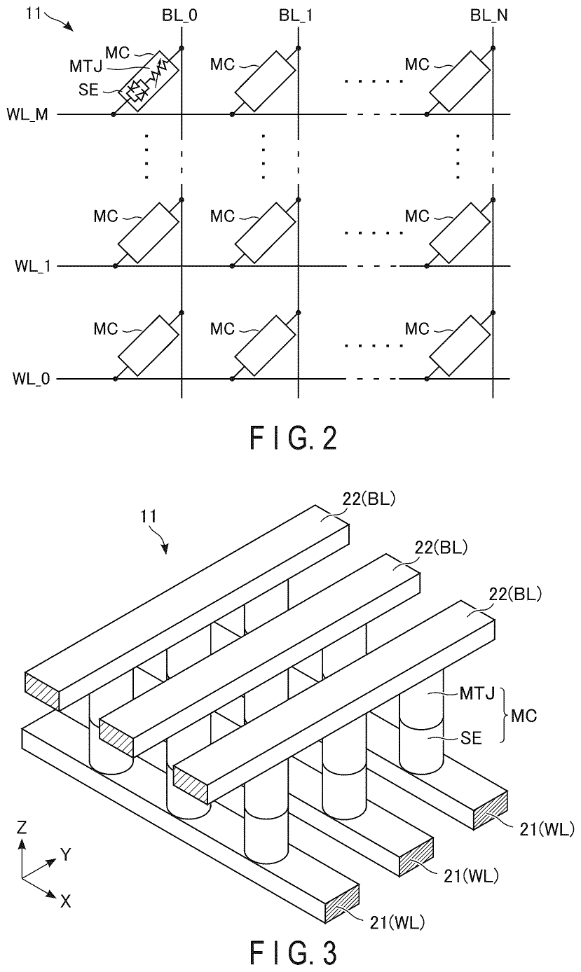

FIG. 2 is a circuit diagram of a memory cell array of the memory device of the first embodiment. As illustrated in FIG. 2, M+1 word lines WL (i.e., WL_0, WL_1, . . . , and WL_M) and N+1 bit lines BL (i.e., BL_0, BL_1, . . . , and BL_N) are located in the memory cell array 11. M and N are positive integers.

Each memory cell MC is coupled to a single word line WL and a single bit line BL. The memory cell MC stores data using dynamically variable resistance, and includes a variable resistance element. The variable resistance element is an element that can switch between a low resistance state and a high resistance state based on an applied voltage. The following description is based on an example in which the variable resistance element is an MTJ element, which will be described later. Other examples of the variable resistance element include a phase-change element.

Each memory cell MC includes a single MTJ element MTJ and a single switching element SE. In each memory cell MC, the MTJ element MTJ and the switching element SE are coupled in series. The switching element SE of each memory cell MC is coupled to a single word line WL. The MTJ element MTJ of each memory cell MC is coupled to a single bit line BL.

The MTJ element MTJ exhibits a tunnel magnetoresistive effect, and, in one example, is an element including a magnetic tunnel junction (MTJ). The MTJ element MTJ is also referred to as a magnetoresistive effect element MTJ. The MTJ element MTJ is a variable resistance element that can switch between a low resistance state and a high resistance state. The MTJ element MTJ can store 1-bit data using a difference between the two resistance states. In one example, the MTJ element MTJ stores “0” data according to the low resistance state and “1” data according to the high resistance state. The following description is based on this example.

The switching element SE is an element that electrically couples or uncouples its both terminals. The switching element SE has two terminals. When a voltage applied between the two terminals in a first direction is lower than a first threshold, the switching element SE is in a high resistance state, or, in one example, an electrically non-conductive state (OFF state). When the voltage applied between the two terminals in the first direction rises to be equal to or higher than the first threshold, the switching element SE enters a low resistance state, or, in one example, an electrically conductive state (ON state). When the voltage applied between the two terminals of the switching element SE in the low resistance state in the first direction falls to be lower than the threshold voltage, the switching element SE enters the high resistance state. The switching element SE has the same function as the function of switching between the high resistance state and the low resistance state based on the magnitude of the voltage applied in the first direction also in a second direction opposite to the first direction. That is, the switching element SE is a bidirectional switching element. The switching element enters the ON state when the voltage applied between the two terminals rises to be equal to or higher than a threshold voltage Vth in any one of the first direction and the second direction. The switching element enters the OFF state when the voltage applied between the two terminals falls to be lower than the threshold voltage Vth in any one of the first direction and the second direction. With the ON or OFF state of the switching element SE, the presence or absence of supply of a current to the MTJ element MTJ coupled to the switching element SE, that is, selection or non-selection of the MTJ element MTJ can be controlled.

FIG. 3 is a perspective view of a part of the memory cell array of the memory device of the first embodiment. As illustrated in FIG. 3, a plurality of conductors 21 and a plurality of conductors 22 are provided.

The conductors 21 each have a linear shape, extend in the X direction, and are aligned in the Y direction. Each conductor 21 functions as a single word line WL.

The conductors 22 are located farther in the Z direction than the conductors 21. The conductors 22 each have a linear shape, extend in the Y direction, and are aligned in the X direction. Each conductor 22 functions as a single bit line BL.

A single memory cell MC is provided at each of the intersections of the conductors 21 and the conductors 22. Each memory cell MC includes a structure functioning as the switching element SE and a structure functioning as the MTJ element MTJ. Each of the structure functioning as the switching element SE and the structure functioning as the MTJ element MTJ includes one or more layers. In one example, the structure functioning as the MTJ element MTJ is located on an upper surface of the structure functioning as the switching element SE. A lower surface of the memory cell MC is in contact with an upper surface of a single conductor 21. An upper surface of the memory cell MC is in contact with a lower surface of a single conductor 22.

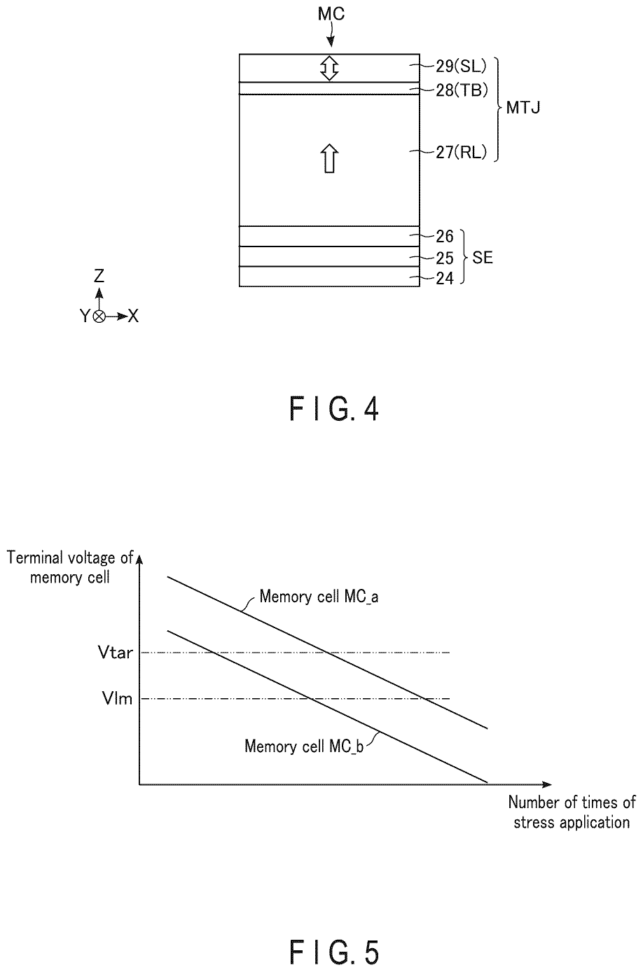

FIG. 4 illustrates an exemplary cross section of the structure of the memory cell of the memory device of the first embodiment. The variable resistance material 25 is a material exhibiting dynamically variable resistance, and, in one example, has a layer shape. The variable resistance material 25 is a switching element between two terminals where a first terminal of the two terminals is one of the upper surface and the lower surface of the variable resistance material 25, and a second terminal of the two terminals is the other of the upper surface and the lower surface of the variable resistance material 25. While a voltage applied between the two terminals is lower than a threshold voltage, the variable resistance material 25 is in a “high resistance” state, for example, an electrically non-conductive state. When the voltage applied between the two terminals rises to be equal to or higher than the threshold voltage, the variable resistance material enters a “low resistance” state, for example, an electrically conductive state. When the voltage applied between the two terminals of the variable resistance material 25 in the low resistance state falls to be lower than the threshold voltage, the variable resistance material 25 enters the high resistance state.

In one example, the variable resistance material 25 includes an insulator and a dopant introduced into the insulator by ion implantation. In one example, the insulator includes an oxide, or SiO₂ or a material consisting substantially of SiO₂. In one example, the dopant includes arsenic (As) and germanium (Ge). The description “consisting (or formed) substantially of” and similar terms are meant to permit a component “consisting substantially of” something to contain unintended impurities.

The switching element SE can further include a lower electrode 24 and an upper electrode 26. FIG. 4 illustrates such an example. The variable resistance material 25 is located on an upper surface of the lower electrode 24, and the upper electrode 26 is located on an upper surface of the variable resistance material 25.

The MTJ element MTJ includes a ferromagnetic layer 27, an insulating layer 28, and a ferromagnetic layer 29. As an example, as illustrated in FIG. 4, the insulating layer 28 is located on an upper surface of the ferromagnetic layer 27, and the ferromagnetic layer 29 is located on an upper surface of the insulating layer 28.

The ferromagnetic layer 27 is a layer of a material exhibiting ferromagnetism. The ferromagnetic layer 27 has an easy magnetization axis in a direction piercing through interfaces among the ferromagnetic layer 27, the insulating layer 28, and the ferromagnetic layer 29, at an angle of 45° through 90° to the interfaces in one example, or in a direction orthogonal to the interfaces in one example. A magnetization direction of the ferromagnetic layer 27 is unchangeable even by reading and writing of data in the memory cell MC. The ferromagnetic layer 27 can function as a so-called reference layer (RL). The ferromagnetic layer 27 may include a plurality of layers. Hereinafter, the ferromagnetic layer 27 may be referred to as a reference layer RL.

The insulating layer 28 is a layer of an insulator. In one example, the insulating layer 28 includes or consists substantially of magnesium oxide (MgO) and functions as a so-called tunnel barrier (TB).

The ferromagnetic layer 29 is a layer of a material exhibiting ferromagnetism. The ferromagnetic layer 29 includes or consists substantially of, for example, cobalt iron boron (CoFeB) or iron boride (FeB). The ferromagnetic layer 29 has an easy magnetization axis in a direction piercing through interfaces among the ferromagnetic layer 27, the insulating layer 28, and the ferromagnetic layer 29, at an angle of 45° through 90° to the interfaces in one example, or in a direction orthogonal to the interfaces in one example. A magnetization direction of the ferromagnetic layer 29 is variable by data writing to the memory cell MC, and the ferromagnetic layer 29 can function as a so-called storage layer (SL). Hereinafter, the ferromagnetic layer 29 may be referred to as a storage layer SL.

While the magnetization direction of the storage layer SL is parallel to the magnetization direction of the reference layer RL, the MTJ element MTJ has a certain low resistance. While the magnetization direction of the storage layer SL is antiparallel to the magnetization direction of the reference layer RL, the MTJ element MTJ has a resistance higher than a resistance in the case in which the magnetization direction of the storage layer SL and the magnetization direction of the reference layer RL are parallel.

When a current having a magnitude equal to or larger than a magnitude of a write current Icp flows from the storage layer SL toward the reference layer RL, the magnetization direction of the storage layer SL becomes parallel to the magnetization direction of the reference layer RL. When a current having a magnitude equal to or larger than a magnitude of a write current Icap flows from the reference layer RL toward the storage layer SL, the magnetization direction of the storage layer SL becomes antiparallel to the magnetization direction of the reference layer RL.

The MTJ element MTJ may include an additional layer. The position of the ferromagnetic layer 27 and the position of the ferromagnetic layer 29 may be exchanged.

FIG. 5 illustrates an example of a change in the terminal voltage of the memory cell of the memory device of the first embodiment. As illustrated in FIG. 5, the memory cell MC has a smaller terminal voltage in a case where the number of times of receiving stress is larger. The stress includes that a current flows through the memory cell MC and that the memory cell MC receives a voltage. The memory cell MC has unintended variations in characteristics. The terminal voltage of the memory cell MC before the memory cell MC is subjected to first stress can be different depending on the memory cell MC. That is, the first terminal voltage of a certain memory cell MC_a is higher than the terminal voltage of another memory cell MC_b.

FIG. 5 illustrates, as an example, that the terminal voltage changes of the memory cell MC_a and the memory cell MC_b have the same slope, but the terminal voltage changes of the memory cell MC_a and the memory cell MC_b may have different slopes.

FIG. 5 illustrates the linear change of the terminal voltage as an example, but actually, although the terminal voltage decreases linearly from a broad viewpoint, the terminal voltage may increase or greatly decrease locally.

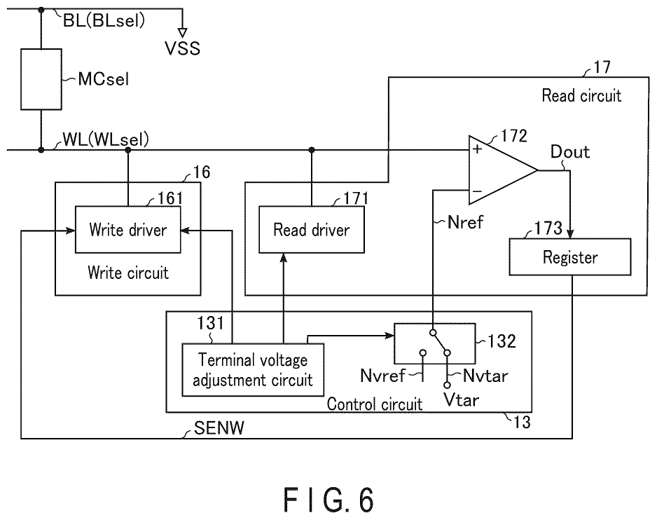

FIG. 6 illustrates some components of the memory device of the first embodiment and the coupling of the components. More specifically, FIG. 6 illustrates the components of the write circuit 16, the read circuit 17, and the control circuit 13. FIG. 6 illustrates a state in which a certain memory cell MC is selected. That is, as described above with reference to FIG. 1, the row selector 14 selects one word line WL, and the column selector 15 selects one bit line BL. One memory cell MC coupled to one word line WL in the selected state and one bit line BL in the selected state is in a selected state. The word line WL, the bit line BL, and the memory cell MC illustrated in FIG. 6 are in a selected state. Hereinafter, the word line WL in the selected state may be referred to as a selected word line WLsel. The bit line BL in the selected state may be referred to as a selected bit line BLsel. The memory cell MC in the selected state may be referred to as a selected memory cell MCsel.

As illustrated in FIG. 6, the write circuit 16 includes a write driver 161. In one example, the write driver 161 is a circuit that applies one or more write voltages having a fixed magnitude to the interconnect connected to the write driver 161, and is a constant voltage circuit. In another example, the write driver 161 is a circuit that applies a write voltage having a fixed magnitude to the interconnect connected to the write driver 161, and is a constant voltage circuit. The write driver 161 is coupled to the selected word line WLsel.

The write driver 161 receives an enable signal SENW. The write driver 161 operates while the enable signal SENW has a valid level. In one example, the valid level is a high level (or “H” level) and the following description is based on this example.

The read circuit 17 includes a read driver 171, an operational amplifier circuit (comparison circuit) 172, and a register 173. In one example, the read driver 171 is a circuit that applies a voltage having a fixed magnitude to the interconnect coupled to the read driver 171, and is a constant voltage circuit. In another example, the read driver 171 is a circuit that applies a read current having a fixed magnitude to the interconnect coupled to the read driver 171, and is a constant voltage circuit.

The operational amplifier circuit 172 is coupled to the selected word line WLsel at non-inverting input. The operational amplifier circuit 172 is coupled to a node Nref at inverting input. The operational amplifier circuit 172 outputs digital data Dout. The data Dout has a high level in a case where a voltage received at the non-inverting input exceeds a voltage received at the inverting input. The data Dout has a low level in a case where a voltage received at the non-inverting input falls to be lower than a voltage received at the inverting input.

The register 173 is a circuit that holds received data. The register 173 receives the data Dout from the operational amplifier circuit 172. The register 173 outputs the enable signal SENW at a level based on the held data. The register 173 outputs the high-level enable signal SENW while the high-level data is held. The register 173 outputs the low-level enable signal SENW while the low-level data is held. Once the register 173 receives the low-level data Dout and is in a state of holding the low-level data, the register keeps holding the low-level data regardless of the level of the received data Dout until being reset. Alternatively, once the register 173 receives the low-level data Dout and is in a state of holding the low-level data, the register 173 is controlled so as to keep holding the low-level data regardless of the level of the received data Dout until being reset.

The control circuit 13 includes a terminal voltage adjustment circuit 131 and a switching circuit 132.

The terminal voltage adjustment circuit 131 is a circuit that executes terminal voltage adjustment. The terminal voltage adjustment refers to adjusting the terminal voltage of the selected memory cell MCsel. The terminal voltage adjustment circuit 131 controls the write driver 161, the read driver 171, and the operational amplifier circuit 172 to execute voltage adjustment. The terminal voltage adjustment circuit 131 instructs the read driver 171 to apply a read bias for acquiring data based on the state of the selected memory cell MC. The terminal voltage adjustment circuit 131 instructs the write driver 161 to write data. In one example, the terminal voltage adjustment circuit 131 monitors the data Dout or the data held in the register 173, and cuts off a path through which the data Dout is supplied to the register 173 in a case where the low-level data is held in the register 173. In another example, the terminal voltage adjustment circuit 131 monitors the data Dout or the data held in the register 173, and controls the register 173 so that the register 173 does not hold the data Dout newly supplied until the terminal voltage adjustment circuit 131 resets the register 173 in a case where the low-level data is held in the register 173. In this example, the reset is performed every time the memory cell MC whose terminal voltage is to be adjusted is selected.

The switching circuit 132 is a circuit that couples the node Nref to one of the nodes Nvref and Nvtar that is dynamically selected. The coupling of the switching circuit 132 is controlled by the terminal voltage adjustment circuit 131.

The node Nvref is coupled to the node Nref during data reading and receives a voltage Vref. The voltage Vref is used to determine the data stored in the selected memory cell MCsel based on the selected memory cell MCsel, more specifically, the potential of the non-inverting input of the operational amplifier circuit 172.

The node Nvtar is coupled to the node Nref during the terminal voltage adjustment, and receives an upper limit voltage Vtar. The upper limit voltage Vtar will be described later.

### 1.2. Operation

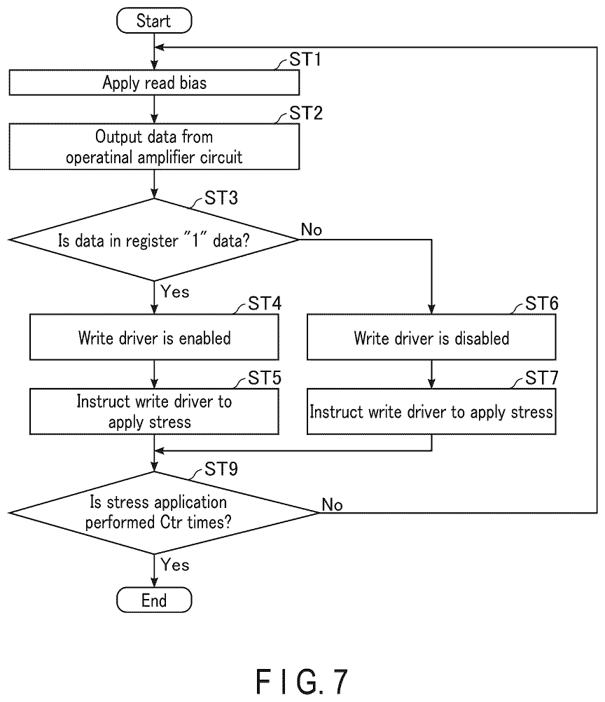

FIG. 7 illustrates a flow of the operation of the memory device of the first embodiment. Specifically, FIG. 7 illustrates a flow of terminal voltage adjustment in the memory device 1. The flow of FIG. 7 is performed for one selected memory cell MCsel. In one example, the flow of FIG. 7 is repeated so that the flow of FIG. 7 is performed each of a plurality of or all memory cells MC. In one example, the terminal voltage adjustment circuit 131 controls the row selector 14 and the column selector 15 to bring the memory cell MC to be subjected to the terminal voltage adjustment into a selected state. During the flow of FIG. 7, the node Nref is coupled to the node Nvtar by the switching circuit 132.

The flow of FIG. 7 is started by the terminal voltage adjustment circuit 131 after one memory cell MC is brought into a selected state by the control of the terminal voltage adjustment circuit 131 or the control circuit 13. The flow of FIG. 7 is performed by the terminal voltage adjustment circuit 131. In one example, the flow of FIG. 7 is performed before the shipment of the memory device 1.

A plurality of, particularly all, terminal voltages in the memory device 1 are required to fall within a certain range. For this purpose, stress is applied to the formed switching element SE by the terminal voltage adjustment, and each terminal voltage is lowered to the upper limit voltage Vtar or less. As described above with reference to FIG. 5, the characteristics of the memory cells MC are different when formed, and thus the number of times of stress application required to be applied until the terminal voltage of each of the memory cells MC becomes equal to or lower than the upper limit voltage Vtar is different. The upper limit voltage Vtar may be a terminal voltage in a case where the memory cell MC is in the low resistance state or a terminal voltage in a case where the memory cell MC is in the high resistance state.

As illustrated in FIG. 7, a read bias is applied to the selected memory cell MCsel (step ST1). In one example, the terminal voltage adjustment circuit 131 instructs the read circuit 17 to flow a current through the selected memory cell MCsel. In one example, the current has the same magnitude as that of the current used in reading data from the memory cell MC. In another example, the terminal voltage adjustment circuit 131 instructs the read circuit 17 to apply a voltage to the selected memory cell MCsel. In one example, the voltage has the same magnitude as that of the voltage used in reading data from the memory cell MC.

By step ST1, a potential Vwl based on the terminal voltage of the selected memory cell MCsel appears on the selected word line WLsel (or, the non-inverting input of the operational amplifier circuit 172). The potential (selected word line potential) Vwl has substantially the same magnitude as that of the terminal voltage of the selected memory cell MCsel. In the specification and claims, “substantially the same” means that two or more “substantially the same” elements are intended to be the same, but are not completely the same due to the limitations of manufacturing and/or measurement techniques.

Data Dout is output from the operational amplifier circuit 172 (step ST2). The data Dout is held in the register 173. In a case where the magnitude of the selected word line potential Vwl is larger than the magnitude of the upper limit voltage Vtar, the data Dout has a high level, and “1” data is held in the register 173. In a case where the magnitude of the selected word line potential Vwl is lower than the magnitude of the upper limit voltage Vtar, the data Dout has a low level, and “0” data is held in the register 173.

In a case where the data in the register 173 has “1” data (step ST3_Yes), the write driver 161 is in an enabled state (step ST4). Step ST4 continues to step ST5.

In a case where the data in the register 173 does not have “1” data (step ST3_Yes), the write driver 161 is in a disabled state (step ST6). Step ST6 continues to step ST7.

By step ST5, the terminal voltage adjustment circuit 131 instructs the write driver 161 to apply stress to the selected memory cell MCsel. Specifically, in one example, the terminal voltage adjustment circuit 131 causes the write driver 161 to apply a voltage between the word line WL and the bit line BL. In one example, the terminal voltage adjustment circuit 131 causes the write driver 161 in the form of a constant voltage circuit to apply a voltage having a magnitude that enables the write current Icap to flow through the memory cell MC.

In another example, the terminal voltage adjustment circuit 131 causes the write circuit 16 to flow a current through the selected memory cell MCsel. In one example, the terminal voltage adjustment circuit 131 causes a write current Icap to flow through the write driver 161 in the form of a constant current circuit.

The write driver 161 is enabled, and thus the write driver 161 executes the application of a voltage or the supply of a current according to the instruction. Step ST5 continues to step ST9.

By step ST7, the terminal voltage adjustment circuit 131 instructs the write driver 161 to apply stress to the selected memory cell MCsel. The operation performed by step ST7 by the terminal voltage adjustment circuit 131 is the same as the operation performed by step ST5. The write driver 161 is disabled, and thus the write driver 161 does not execute (cannot execute) the application of the voltage or the supply of the current according to the instruction. Step ST7 continues to step ST9.

In a case where the number of times of the execution of the instruction of stress application by the terminal voltage adjustment circuit 131, that is, the sum of the number of times of the execution of step ST5 and the number of times of the execution of step ST7 is equal to or larger than a threshold value Ctr (step ST9_Yes), the flow ends. The threshold value Ctr has a predetermined magnitude. That is, the terminal voltage adjustment is executed the same number of times for each selected memory cell MCsel. However, in the case of step ST7, the application of stress itself does not occur. The threshold value Ctr is set to a value that causes a specific number of or all the memory cells MC to have a terminal voltage lower than the upper limit voltage Vtar in a case where the specific number of or all the memory cells MC receive the stress of the number of times of the threshold value Ctr based on the initial (before the terminal voltage adjustment) terminal voltages of a plurality of, representative, or all the memory cells MC of the memory device 1 and the degree of a decrease in the terminal voltage based on the applied stress.

In a case where the number of times of the execution of the instruction of stress application by the terminal voltage adjustment circuit 131 is less than the threshold value Ctr (step ST9_No), the flow continues to step ST1.

### 1.3. Advantages (Effects)

According to the first embodiment, as described below, the memory device 1 in which variations in characteristics are suppressed is provided.

It is conceivable that the stress application in step ST5 is performed equally to each memory cell MC by the same number (for example, the threshold value Ctr). However, as described above with reference to FIG. 5, the initial terminal voltage of the memory cell MC may vary, and how the terminal voltage decreases according to the number of times of stress application may also vary. Therefore, even after receiving the same number of times of stress, the terminal voltage of a certain memory cell MC may exceed the upper limit voltage Vtar. In order to cope with this, if the number of times of stress application is increased, the terminal voltage of the memory cell MC having a low initial terminal voltage and/or whose terminal voltage is apt to decrease due to stress application may fall to be lower than the lower limit of the terminal voltage after the same number of times of stress application. As a result, variations in the terminal voltage of the memory cell MC are large.

According to the first embodiment, information on whether the terminal voltage falls to be lower than the upper limit is acquired for each memory cell MC, and the execution and non-execution of the next stress application are determined based on the acquired information. The sum of the number of times of stress application to be executed and the number of times of non-execution of stress application is the same (the number of threshold values Ctr) regardless of the memory cell MC, and the total number of times is set so that the terminal voltage of any memory cell MC also falls to be lower than the upper limit voltage Vtar, thereby suppressing the occurrence of the memory cell MC having the terminal voltage exceeding the upper limit voltage Vtar after the terminal voltage adjustment. In the adjustment of the terminal voltage for each memory cell MC, after the terminal voltage of the memory cell MC falls to be lower than the upper limit voltage Vtar, no stress is applied. Therefore, the occurrence of the memory cell MC having an excessively small terminal voltage (so as to fall to be lower than the lower limit) after the total number of times of stress application is suppressed. Therefore, variations in the terminal voltage of the memory cell MC are small.

### 1.4. Modified Example

The stress application to the selected memory cell MCsel for the terminal voltage adjustment may be performed by a driver provided exclusively for the terminal voltage adjustment, instead of being performed by using the write circuit 16.

The comparison between the magnitude of the selected word line potential Vwl and the magnitude of the upper limit voltage Vtar may be performed by a dedicated comparison circuit instead of being performed by using the operational amplifier circuit 172.

### 2. Second Embodiment

The second embodiment is different from the first embodiment in the determination of further execution or non-execution of stress application to the selected memory cell MCsel.

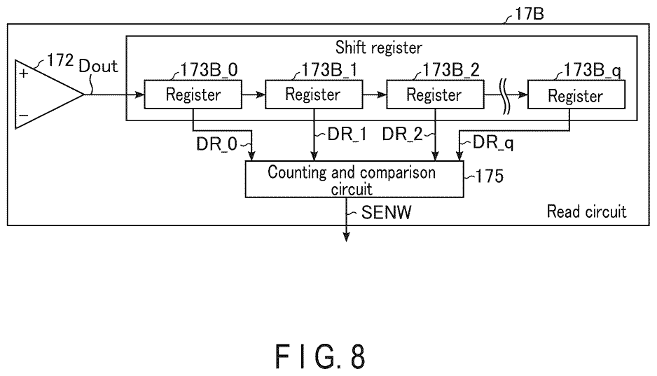

FIG. 8 illustrates components of a read circuit of a memory device of a second embodiment and the coupling of the components. As illustrated in FIG. 8, a memory device 1B of the second embodiment includes a read circuit 17B. The read circuit 17B includes an odd number of a plurality of registers 173B (173B_0, 173B_1, . . . , and 173B_q) and a counting and comparison circuit 175.

The registers 173B hold the value of data Dout from the operational amplifier circuit 172. Every time the data Dout is output from the operational amplifier circuit 172, the different register 173B receives and holds the data Dout. In one example, the register 173B constitutes a shift register. The shift register receives a clock signal synchronized with the output timing of the data Dout from the operational amplifier circuit 172, and operates in synchronization with the clock signal. Each register 173B outputs the held data and newly holds the data received by the register 173B in synchronization with the clock signal. The register 173B_0 outputs data DR_0. Similarly, the registers 173B_1, 173B_2, . . . , and 173B_q output data DR_1, DR_2, . . . , and DR_q, respectively. The plurality of pieces of data DR have values based on levels of different pieces of data Dout output at different timings from the operational amplifier circuit 172. That is, the plurality of pieces of data DR respectively reflect a plurality of comparison results by the operational amplifier circuit 172 obtained by repeating step ST2 of the flow of FIG. 7 of the first embodiment.

In another example, each register 173B is coupled at an input to an output of the operational amplifier circuit 172 via a switch. Only one register 173B is coupled to the output of the operational amplifier circuit 172 by each switch.

The counting and comparison circuit 175 is a circuit that receives a plurality of pieces of data, counts the number of a plurality of values of the received data, and compares counting results. The counting and comparison circuit 175 receives the output of each register 173B. The counting and comparison circuit 175 counts the data DR from each register 173B, that is, the data Dout for each value. That is, the counting and comparison circuit 175 counts the number of “0” data among the plurality of data DR and the number of “1” data among the plurality of data DR. The counting and comparison circuit 175 outputs a high-level enable signal SENW in a case where the number of “1” data exceeds the number of “0” data. The counting and comparison circuit 175 outputs a low-level enable signal SENW in a case where the number of “1” data does not exceed the number of “0” data.

Similarly to the register 173 of the first embodiment, once the counting and comparison circuit 175 starts to output the high-level enable signal SENW during the terminal voltage adjustment of the selected memory cell MCsel, the counting and comparison circuit 175 maintains the high-level enable signal SENW for the following period in the terminal voltage adjustment.

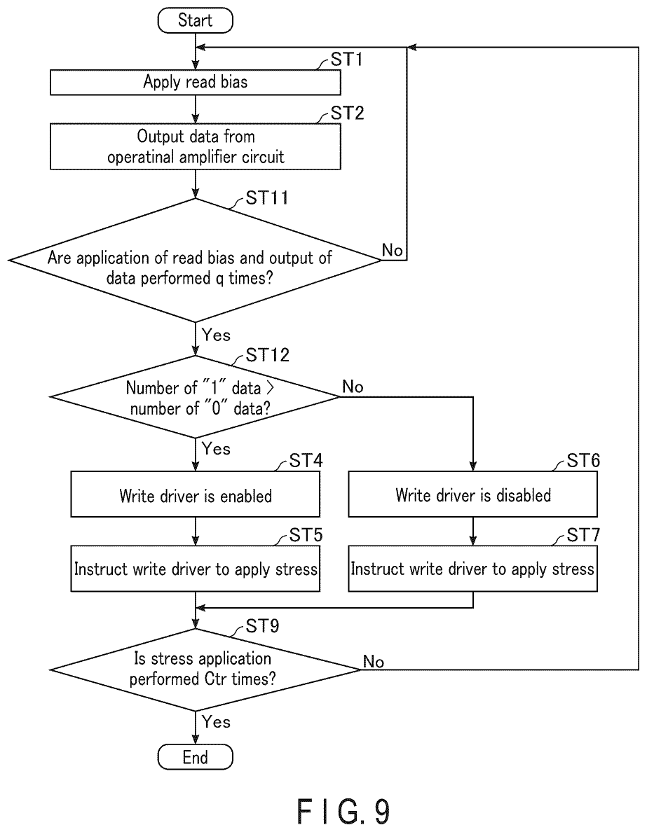

FIG. 9 illustrates a flow of the operation of the memory device of the second embodiment. As illustrated in FIG. 9, step ST2 continues to step ST11. A terminal voltage adjustment circuit 131 determines whether the set of the application of a read bias (step ST1) and the output of the data Dout from the operational amplifier circuit 172 (step ST2) has been performed q times from the start of the flow of FIG. 9 (step ST11). In a case where the set has not been performed q times (step ST11_No), the flow proceeds to step ST1. In a case where the set has been performed q times (step ST11_Yes), the flow proceeds to step ST12.

In a case where the number of “1” data in the registers 173 exceeds the number of “0” data in the registers 173 (step ST12_Yes), the flow continues to step ST4. In a case where the number of “1” data in the registers 173 does not exceed the number of “0” data in the registers 173 (step ST12_No), the flow continues to step ST6.

According to the second embodiment, similarly to the first embodiment, information on whether the terminal voltage falls to be lower than the upper limit is acquired for each memory cell MC, and the execution and non-execution of the next stress application are determined based on the acquired information. Therefore, the same advantages as those of the first embodiment can be obtained.

According to the second embodiment, as described below, variations in the terminal voltage of the memory cell MC are further suppressed. As described above with reference to FIG. 5, the terminal voltage of the memory cell MC may rise or greatly fall each time stress is applied. Therefore, even if the terminal voltage of the selected memory cell MCsel falls to be lower than the upper limit voltage Vtar at a certain point of time during the terminal voltage adjustment of a certain selected memory cell MCsel, this may be accidental. According to the second embodiment, data is read from the selected memory cell MCsel a plurality of times and in a case where the number of times of the terminal voltage falling to be lower than the upper limit voltage Vtar exceeds the number of times of the terminal voltage exceeding the upper limit voltage Vtar, it is determined that the terminal voltage falls to be lower than the upper limit voltage Vtar. As a result, even if the terminal voltage of the selected memory cell MCsel accidentally falls to be lower than the upper limit voltage Vtar only once, this alone does not stop the stress application. Therefore, the terminal voltage of the selected memory cell MCsel can be adjusted to less than the upper limit voltage Vtar with high accuracy. This leads to the suppression of variations in the terminal voltage of the memory cell MC.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a memory cell that includes a variable resistance element and a switching element;
a first interconnect coupled to the memory cell;
a first driver configured to generate a first potential based on a terminal voltage of the memory cell on the first interconnect;
a comparison circuit configured to output first data having a first level in a case where the first potential exceeds a reference potential and output the first data having a second level in a case where the first potential falls to be lower than the reference potential;
a register configured to hold the first data and output a first signal having a level based on the first data; and
a second driver configured to receive the first signal and respond to an instruction to apply stress to the memory cell from outside to execute the application of the stress in a case where the first signal has the first level and not to execute the application of the stress in a case where the first signal has the second level.

2. The memory device according to claim 1, further comprising
a control circuit that repeatedly executes a set of an instruction to generate the first potential to the first driver and an instruction to apply the stress to the second driver.

3. The memory device according to claim 2, wherein
the applying of the stress includes applying a voltage to the memory cell or flowing a current through the memory cell.

4. The memory device according to claim 1, wherein
the applying of the stress includes applying a voltage to the memory cell or flowing a current through the memory cell.

5. The memory device according to claim 1, wherein
the second driver is configured to apply a voltage having a direction and a magnitude based on data to be written in the memory cell to the memory cell, or to cause a current having a direction and a magnitude based on the data to be written in the memory cell to flow through the memory cell.

6. The memory device according to claim 1, wherein
the variable resistance element includes a magnetoresistive effect element.

7. A memory device comprising:
a memory cell including a variable resistance element and a switching element;
a first interconnect coupled to the memory cell;
a first driver configured to generate a first potential based on a terminal voltage of the memory cell on the first interconnect;
a comparison circuit configured to output first data having a first level in a case where the first potential exceeds a reference potential and output the first data having a second level in a case where the first potential falls to be lower than the reference potential;
a plurality of registers configured to hold the first data;
a comparison and counting circuit configured to output a first signal having a third level in a case where a first number of the data of the second level held in the registers exceeds a second number of the data of the first level held in the registers and having a fourth level in a case where the first number falls to be lower than the second number; and
a second driver configured to receive the first signal from the comparison and counting circuit and respond to an instruction to apply stress to the memory cell from outside to execute the application of the stress in a case where the first signal has the third level and not to execute the application of the stress in a case where the first signal has the fourth level.

8. The memory device according to claim 7, further comprising
a control circuit that repeatedly executes a set of an instruction to generate the first potential to the first driver and an instruction to apply the stress to the second driver.

9. The memory device according to claim 8, wherein
the applying of the stress includes applying a voltage to the memory cell or flowing a current through the memory cell.

10. The memory device according to claim 7, wherein
the applying of the stress includes applying a voltage to the memory cell or flowing a current through the memory cell.

11. The memory device according to claim 7, wherein
the second driver is configured to apply a voltage having a direction and a magnitude based on data to be written in the memory cell to the memory cell, or to cause a current having a direction and a magnitude based on the data to be written in the memory cell to flow through the memory cell.

12. The memory device according to claim 7, wherein
the variable resistance element includes a magnetoresistive effect element.
